(19) United States
(12) Patent Application Publication
(10) Pub. No.: US 2019/0212066 A1
(43) Pub. Date: Jul. 11, 2019

(54) WATER-COOLING RADIATOR ASSEMBLY WITH INTERNAL HORIZIONTAL PARTITION MEMBERS AND FLOW DISTURBING MEMBERS

(71) Applicant: ASIA VITAL COMPONENTS CO., LTD., New Taipei City (TW)

(72) Inventor: Wen-Ji Lan, New Taipei City (TW)

(21) Appl. No.: 15/867,721

(22) Filed: Jan. 11, 2018

(51) Int. Cl. F28D 9/00; F28F 3/02; F28F 9/26; H05K 7/20; G06F 1/20

(52) U.S. Cl. CPC F28D 9/0025; F28F 3/027; F28D 2021/0031; H05K 7/20263; G06F 1/20; F28F 9/262

(57) ABSTRACT

A water-cooling radiator assembly with internal horizontal partition members and fluid disturbing members includes a liquid-receiving plate unit consisting of a first liquid-receiving plate having a first partition member provided therein to divide an inner space thereof into a first and a second liquid chamber communicable with at least one liquid inlet, and a second liquid-receiving plate having a second partition member provided therein to divide an inner space thereof into a fourth liquid chamber and a third liquid chamber communicable with at least one liquid outlet; a first flow disturbing member selectively arranged in any one of the first, second, third and fourth liquid chambers; and a communicating pipe unit including a first, a second and a third communicating pipe to communicate the second with the fourth liquid chamber, the fourth with the first liquid chamber, and the first with the third liquid chamber, respectively.

### FIELD OF THE INVENTION

The present invention relates to a water-cooling radiator assembly with internal horizontal partition members and fluid disturbing members, and more particularly, to a water-cooling radiator assembly with internal horizontal partition members and fluid disturbing members that provides upgraded heat dissipation effect.

### BACKGROUND OF THE INVENTION

Many electronic elements in a computer will produce a large quantity of heat when the computer operates. Hence, a good heat dissipation system is a key factor that determines the effectiveness and reliability of a computer. In a computer, the workload of the central processing unit (CPU) and the graphic processing unit (GPU) is higher than any other heat-producing elements in the computer, and accordingly, solutions for dissipating heat produced by the CPU and the GPU are no doubt very important. Particularly, the currently available computer games all include highly exquisite images that require computer-aided design (CAD) software with increasingly enhanced functions to achieve. However, the operation of such CAD software will render the CPU and the GPU into a heavy workload state to produce a huge quantity of heat. Heat accumulated in the computer would result in lowered performance of the CPU and GPU, or, in some worse condition, even result in damages or largely shortened service life of the CPU and GPU.

Different water cooling systems are available in the market for lowering the working temperature of the heat-producing electronic elements. A conventional water cooling system generally includes a water-cooling radiator 1 fluid-communicably connected to a pump 1a and a water block 1b via two water pipes. The water block 1b is in contact with a heat-producing element, such as a CPU. The pump 1a drives a cooling liquid, i.e. a working fluid such as water, from the water block 1b to flow into the water-cooling radiator 1, so that heat absorbed and carried by the working fluid is transferred to and dissipated from the water-cooling radiator 1 into ambient air. The pump 1a drives the cooling liquid to continuously circulate between the water-cooling radiator 1 and the water block 1b to enable quick removal of heat from the heat-producing electronic element. FIG. 1 shows a conventional water-cooling radiator structure 1, which includes a plurality of radiating fins 11, a plurality of straight flat pipes 12, and two side water tanks 13. The radiating fins 11 are arranged between any two adjacent flat pipes 12 and the two side water tanks 13 are soldered to the radiating fins 11 and two opposite ends of the flat pipes 12, so that the two side water tanks 13, the radiating fins 11 and the straight flat pipes 12 together constitute the water-cooling radiator structure 1. A first one of the two side water tanks 13 is provided with a water inlet 131 and a water outlet 132, which are separately connected to the above-mentioned two water pipes (not shown).

The working fluid flowed into the first side water tank 13 via the water inlet 131 quickly and straightly flows through the straight flat pipes 12 to the second side water tank 13, and then quickly flows back to the first side water tank 13 via the straight flat pipes 12 and leaves the water-cooling radiator structure 1 via the water outlet 132. Therefore, the time period from the entering to the leaving of the heat-carrying working fluid into and from the water-cooling radiator structure 1 is very short and there is not sufficient time for the heated working fluid to exchange heat with the water-cooling radiator structure 1. As a result, the conventional water-cooling radiator structure 1 could not effectively remove the heat from the working fluid flowing therethrough and has the problem of poor heat dissipation efficiency. In addition, the conventional water-cooling radiator structure 1 is an integral structure, which is not adjustable or changeable according to the internal space of an electronic device that uses the water-cooling radiator structure 1. Therefore, to use the water-cooling radiator structure 1 inside an electronic device, the electronic device must have an independent internal space sufficient for installing the water-cooling radiator structure 1.

### SUMMARY OF THE INVENTION

A primary object of the present invention is to provide a water-cooling radiator assembly that has internal horizontal partition members and fluid disturbing members to provide enhanced heat removal performance.

Another object of the present invention is to provide a water-cooling radiator assembly with internal horizontal partition members and fluid disturbing members, according to which two or more liquid-receiving plates are superposed while vertically spaced from one another and each of the liquid-receiving plates is internally divided by a partition member into two independent liquid chambers, and at least one of the two independent liquid chambers is internally provided with a flow disturbing member that provides structural supporting and flow disturbing effects, so that the flow time of a working liquid flowing through the liquid chambers is increased to effectively upgrade the heat exchange efficiency of the water-cooling radiator assembly.

A further object of the present invention is to provide a water-cooling radiator assembly with internal horizontal partition members and fluid disturbing members, according to which a working liquid can flow between a first and a second liquid-receiving plate via a first, a second and a third communicating pipe, and the first and second liquid-receiving plates are respectively internally divided by a partition member into two independent liquid chambers, such that a part of the working liquid that is in one of the two independent liquid chambers of each liquid-receiving plate and has been cooled can exchange heat with another part of the working liquid that is in the other liquid chamber of the same liquid-receiving plate and still carries heat with it.

A still further object of the present invention is to provide a water-cooling radiator assembly with internal horizontal partition members and fluid disturbing members, according to which different numbers of liquid-receiving plates can be included and different numbers of communicating pipes can be provided at different positions between the liquid-receiving plates to communicate the liquid-receiving plates with one another; and the numbers and the positions of the liquid-receiving plates and the communicating pipes can be actively adjusted according to an internal space available in an electronic device, in which the water-cooling radiator assembly is to be mounted.

A still further object of the present invention is to provide a water-cooling radiator assembly with internal horizontal partition members and fluid disturbing members, according to which two or more liquid-receiving plates are included, and any or all of the liquid-receiving plates can be made of a titanium material that has high metal strength, low weight and good heat transfer efficiency and is corrosion resistant to enable effectively upgraded heat transfer effect and reduced overall weight of the water-cooling radiator assembly.

To achieve the above and other objects, the water-cooling radiator assembly with internal horizontal partition members and fluid disturbing members provided according to the present invention includes a liquid-receiving plate unit, a first flow disturbing member and a communicating pipe unit. The liquid-receiving plate unit includes a first and a second liquid-receiving plate. The first liquid-receiving plate has at least one liquid inlet provided thereon and a first partition member provided therein to divide an inner space of the first liquid-receiving plate into a first liquid chamber and a second liquid chamber; and the second liquid chamber is communicable with the at least one liquid inlet to allow a working liquid to flow into the second liquid chamber via the at least one liquid inlet. The second liquid-receiving plate has at least one liquid outlet provided thereon and a second partition member provided therein to divide an inner space of the second liquid-receiving plate into a third liquid chamber and a fourth liquid chamber; and the third liquid chamber is communicable with the at least one liquid outlet. The first flow disturbing member can be selectively arranged in any one of the first, the second, the third and the fourth liquid chamber. The communicating pipe unit includes a first, a second and a third communicating pipe. The first communicating pipe communicates the second liquid chamber with the fourth liquid chamber, the second communicating pipe communicates the fourth liquid chamber with the first liquid chamber, and the third communicating pipe communicates the first liquid chamber with the third liquid chamber. With the above arrangements, the flow time of the working liquid in the liquid chambers of the liquid-receiving plates can be increased, enabling the water-cooling radiator assembly of the present invention to have improved heat removal performance.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 an assembled perspective view of a prior art water-cooling radiator structure;

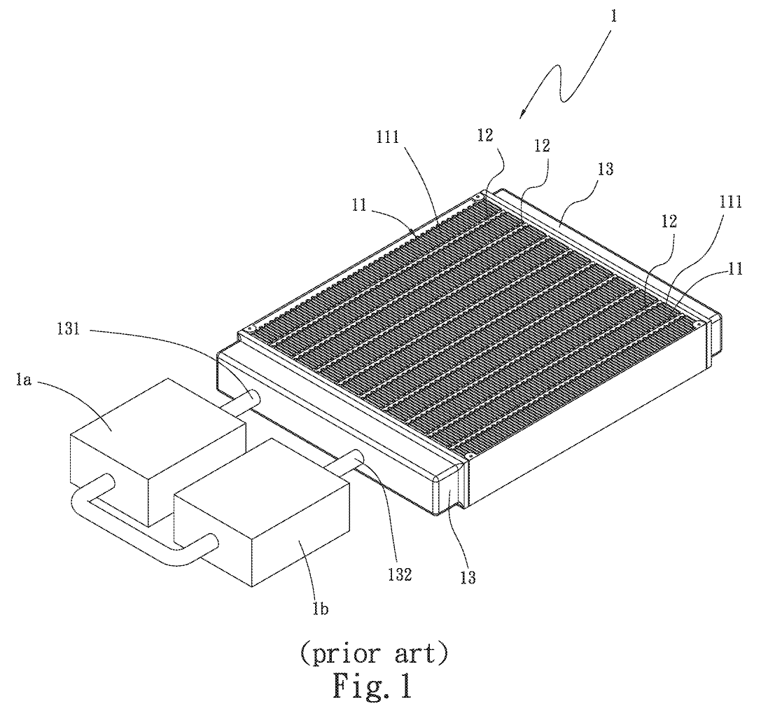

FIG. 2 is an assembled perspective view of a water-cooling radiator assembly with internal horizontal partition members and fluid disturbing members according to a first embodiment of the present invention;

FIG. 2A is an assembled sectional view of the first embodiment of the present invention;

FIG. 3A is an exploded top perspective view of the first embodiment of the present invention;

FIG. 3B is an exploded bottom perspective view of the first embodiment of the present invention;

FIG. 4 is an enlarged view of the circled area 4 in FIGS. 3A, 5A, 7A and 8A;

FIG. 5A is an exploded top perspective view of a water-cooling radiator assembly with internal horizontal partition members and fluid disturbing members according to a second embodiment of the present invention;

FIG. 5B is an assembled sectional view of the second embodiment of the present invention;

FIG. 6A is an exploded top perspective view of a water-cooling radiator assembly with internal horizontal partition members and fluid disturbing members according to a third embodiment of the present invention;

FIG. 6B is an exploded bottom perspective view of the third embodiment of the present invention;

FIG. 6C is an assembled sectional view of the third embodiment of the present invention;

FIG. 6D is an enlarged view of the circled area 6D in FIGS. 6A and 9A;

FIG. 7A is an exploded top perspective view of a water-cooling radiator assembly with internal horizontal partition members and fluid disturbing members according to a fourth embodiment of the present invention;

FIG. 7B is an assembled sectional view of the fourth embodiment of the present invention;

FIG. 8A is an exploded top perspective view of a water-cooling radiator assembly with internal horizontal partition members and fluid disturbing members according to a fifth embodiment of the present invention;

FIG. 8B is an assembled sectional view of the fifth embodiment of the present invention;

FIG. 9A is an exploded top perspective view of a water-cooling radiator assembly with internal horizontal partition members and fluid disturbing members according to a sixth embodiment of the present invention;

FIG. 9B is an exploded bottom perspective view of the sixth embodiment of the present invention;

FIG. 9C is an assembled sectional view of the sixth embodiment of the present invention;

FIG. 10 is an assembled perspective view of a water-cooling radiator assembly with internal horizontal partition members and fluid disturbing members according to a seventh embodiment of the present invention; and

FIG. 11 is an assembled perspective view of a water-cooling radiator assembly with internal horizontal partition members and fluid disturbing members according to an eighth embodiment of the present invention.

### DETAILED DESCRIPTION OF THE PREFERRED EMBODIMENTS

The present invention will now be described with some preferred embodiments thereof and by referring to the accompanying drawings. For the purpose of easy to understand, elements that are the same in the preferred embodiments are denoted by the same reference numerals.

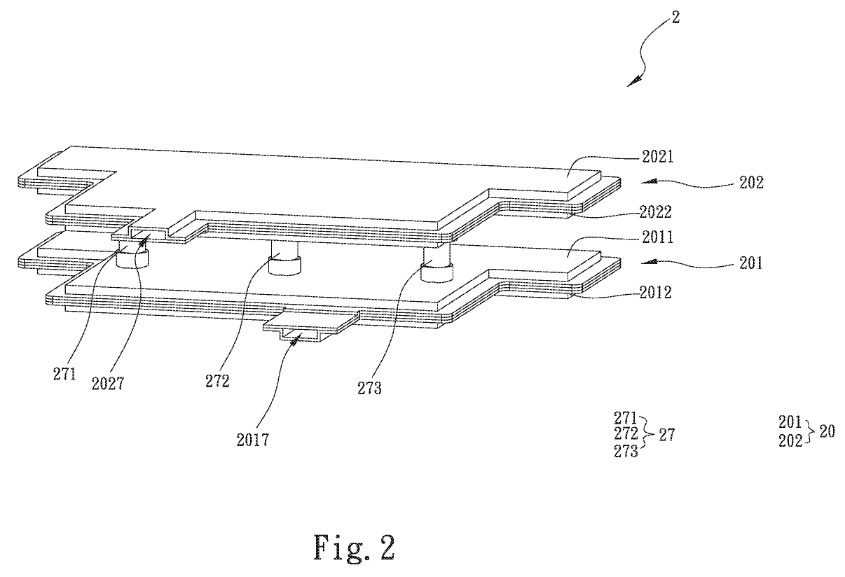

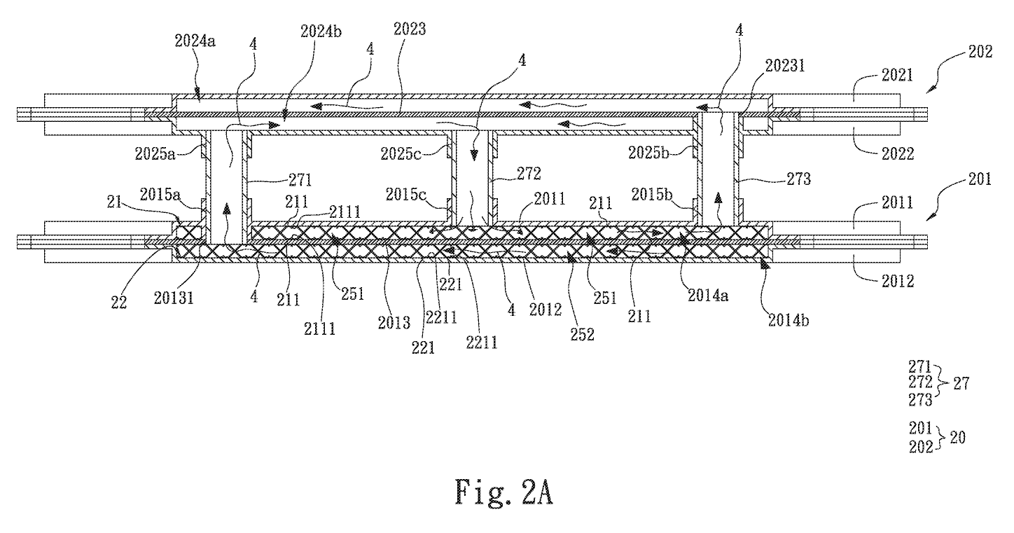

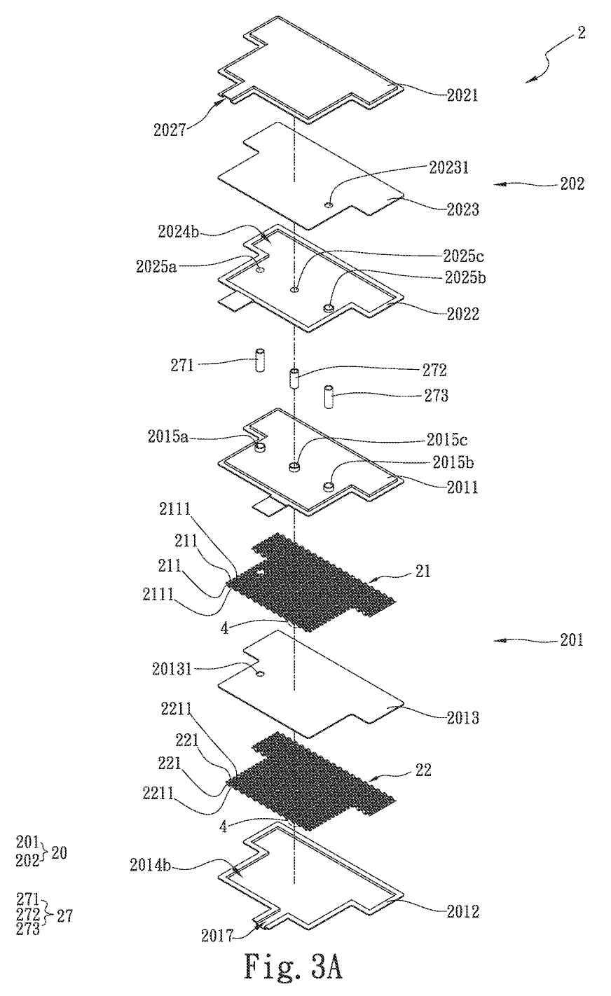

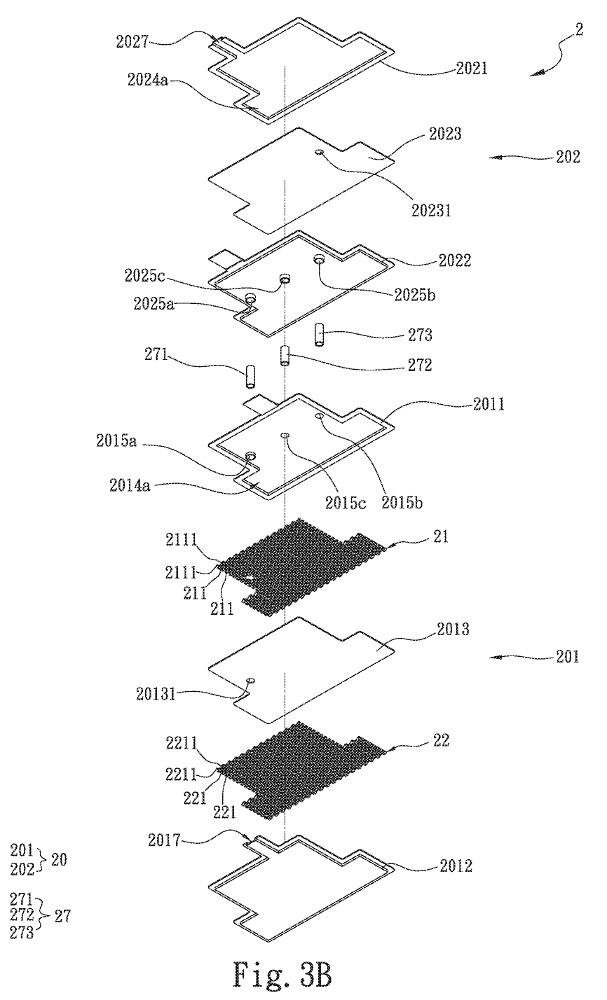

Please refer to FIGS. 2 and 2A, which are assembled perspective and sectional views, respectively, of a water-cooling radiator assembly with internal horizontal partition members and fluid disturbing members according to a first embodiment of the present invention; and to FIGS. 3A and 3B, which are exploded top and bottom perspective views, respectively, of the first embodiment of the present invention. For the purpose of conciseness and clarity, the present invention is also briefly referred to as the water-cooling radiator assembly and generally denoted by reference numeral 2 herein. As shown, the water-cooling radiator assembly 2 includes a liquid-receiving plate unit 20, a first flow disturbing member 21 and a communicating pipe unit 27. The liquid-receiving plate unit 20 includes a first liquid-receiving plate 201 and a second liquid-receiving plate 202, which can be made of gold, silver, copper, iron, titanium, aluminum or stainless steel, or any alloy of these metal materials. The first liquid-receiving plate 201 includes a first top plate member 2011 and a first bottom plate member 2012 closed and connected to each other, at least one liquid inlet 2017, a first opening 2015a and a first partition member 2013. The first partition member 2013 is arranged in the first liquid-receiving plate 201 between the first top plate member 2011 and the first bottom plate member 2012, so as to divide an inner space of the first liquid-receiving plate 201 into a first liquid chamber 2014a and a second liquid chamber 2014b. The second liquid chamber 2014b is communicable with the at least one liquid inlet 2017. The first partition member 2013 is provided with a first hole 20131, which penetrates the first partition member 2013 and is located corresponding to the first opening 2015a formed on the first top plate member 2011 to communicate the first opening 2015a with the second liquid chamber 2014b. The communicating pipe unit 27 includes a first communicating pipe 271, which has an end inserted into the first hole 20131.

In the illustrated first embodiment, the second liquid chamber 2014b is formed between the first bottom plate member 2012 and the first partition member 2013 while the first liquid chamber 2014a is formed between the first top plate member 2011 and the first partition member 2013. In other words, with the first partition member 2013 provided in the first liquid-receiving plate 201, the second liquid chamber 2014b and the first liquid chamber 2014a form two independent chambers in the first liquid-receiving plate 201 and are not directly communicable with each other. In the illustrated first embodiment, there is shown only one liquid inlet 2017 arranged at one lateral side of the first liquid-receiving plate 201, allowing a working liquid 4 to flow into the second liquid chamber 2014b via the liquid inlet 2017. In the illustrated first embodiment, the working liquid 4 is a ketone liquid. However, the working liquid 4 is not limited to the ketone liquid but can be any other liquid that provides heat dissipation effect, such pure water, inorganic compounds, alcohols, liquid metals, coolants and organic compounds.

The second liquid-receiving plate 202 is disposed above and spaced from the first liquid-receiving plate 201. The second liquid-receiving plate 202 includes a second top plate member 2021 and a second bottom plate member 2022 closed and connected to each other, at least one liquid outlet 2027, a second opening 2025a and a second partition member 2023. The second partition member 2023 is arranged in the second liquid-receiving plate 202 between the second top plate member 2021 and the second bottom plate member 2022, so as to divide an inner space of the second liquid-receiving plate 202 into a third liquid chamber 2024a and a fourth liquid chamber 2024b. The third liquid chamber 2024a is communicable with the at least one liquid outlet 2027. The fourth liquid chamber 2024b is communicable with the second opening 2025a, which is formed on and penetrates the second bottom plate member 2022. The second partition member 2023 is not provided on an upper and a lower side thereof with any flow passage. In the illustrated first embodiment, the fourth liquid chamber 2024b is formed between the second bottom plate member 2022 and the second partition member 2023 while the third liquid chamber 2024a is formed between the second top plate member 2021 and the second partition member 2023. In other words, with the second partition member 2023 provided in the second liquid-receiving plate 202, the fourth liquid chamber 2024b and the third liquid chamber 2024a form two independent chambers in the second liquid-receiving plate 202 and are not directly communicable with each other.

In the illustrated first embodiment, there is shown only one liquid outlet 2027 arranged at one lateral side of the second liquid-receiving plate 202 and communicating with the third liquid chamber 2024a. In addition to the first communicating pipe 271, the communicating pipe unit 27 further includes a second and a third communicating pipe 272, 273. The first, second and third communicating pipes 271, 272, 273 can be made of gold, silver, copper, iron, titanium, aluminum or stainless steel, or any alloy of these metal materials. In the first embodiment, the first, second and third communicating pipes 271, 272, 273 are located between the first and the second liquid-receiving plate 201, 202 of the liquid-receiving plate unit 20. The first communicating pipe 271 has an end extended through the first opening 2015a and the first hole 20131 into the second liquid chamber 2014b and another end communicably connected to the second opening 2025a, such that the first communicating pipe 271 communicates the second liquid chamber 2014b with the fourth liquid chamber 2024b via the first opening 2015a and the second opening 2025a. The first communicating pipe 271 has an outer wall surface in tight contact with and connected to the first opening 2015a and the first hole 20131 by means of laser beam welding, welding or leakproof gasket, so as to prevent leakage of the working liquid 4 from the first and the second liquid chamber 2014a, 2014b. It is noted that, in the illustrated first embodiment, the liquid-receiving plates included in the liquid-receiving plate unit 20 are not limited to two in number, and the communicating pipes included in the communicating pipe unit 27 are not limited to three in number. In practical implementation of the present invention, the number of the liquid-receiving plates can be increased according to actual need in heat dissipation. For example, three or four or more liquid-receiving plates can be overlapped while vertically spaced from one another. Similarly, the number of the communicating pipes provided between any two mutually vertically spaced liquid-receiving plates can be increased according to actual need in heat dissipation. For example, five or six communicating pipes can be provided.

The first liquid-receiving plate 201 further includes a third opening 2015b and a fourth opening 2015c, which penetrate the first top plate member 2011. The second communicating pipe 272 has an end communicably connected to the fourth opening 2015c while the third communicating pipe 273 has an end communicably connected to the third opening 2015b. Therefore, the second and the third communicating pipe 272, 273 are communicable with the first liquid chamber 2014a. The second liquid-receiving plate 202 further includes a fifth opening 2025b and a sixth opening 2025c, which penetrate the second bottom plate member 2022. The second communicating pipe 272 has another end communicably connected to the sixth opening 2025c, so that the second communicating pipe 272 communicates the first liquid chamber 2014a with the fourth liquid chamber 2024b. The second partition member 2023 is provided with a second hole 20231, which penetrates the second partition member 2023 and is located corresponding to the fifth opening 2025b to communicate the fifth opening 2025b with the third liquid chamber 2024a. The third communicating pipe 273 has another end extended through the fifth opening 2025b and the second hole 20231 into the third liquid chamber 2024a, so as to communicate the first liquid chamber 2014a with the third liquid chamber 2024a. Similarly, the third communicating pipe 273 has an outer wall surface in tight contact with and connected to the fifth opening 2025b and the second hole 20231 by means of laser beam welding, welding or leakproof gasket, so as to prevent leakage of the working liquid 4 from the third and the fourth liquid chamber 2024a, 2024b.

According to the first embodiment, the water-cooling radiator assembly 2 of the present invention further includes a second flow disturbing member 22. The first and the second flow disturbing member 21, 22 provide the effects of disturbing liquid flows and forming a support in the first liquid-receiving plate 201. The first and the second flow disturbing member 21, 22 can be made of gold, silver, copper, iron, titanium, aluminum or stainless steel, or any alloy of these metal materials. The first and the second flow disturbing member 21, 22 are arranged in the first liquid chamber 2014a and the second liquid chamber 2014b, respectively. In the illustrated first embodiment, the first flow disturbing member 21 in the first liquid chamber 2014a has an upper side in contact with an inner surface of the first top plate member 2011 and a lower side in contact with an upper surface of the first partition member 2013; and the second flow disturbing member 22 in the second liquid chamber 2014b has an upper side in contact with a lower surface of the first partition member 2013 and a lower side in contact with an inner surface of the first bottom plate member 2012. In an operable embodiment of the present invention, the first flow disturbing member 21 can be omitted from the first liquid chamber 2014a, so that the water-cooling radiator assembly 2 has only the second flow disturbing member 22 arranged in the second liquid chamber 2014b. Alternatively, according to another operable embodiment, the second flow disturbing member 22 can be omitted from the second liquid chamber 2014b while the first liquid chamber 2014a has the first flow disturbing member 21 arranged therein.

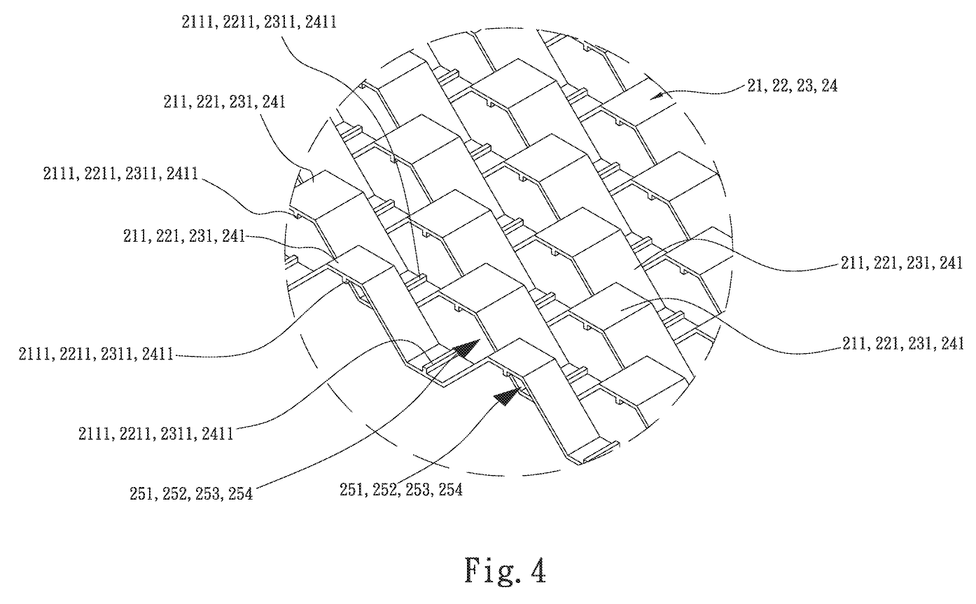

FIG. 4 is an enlarged view of the circled area 4 in FIG. 3A. Please refer to FIGS. 2A, 3A and 3B along with FIG. 4. The first flow disturbing member 21 includes a plurality of first flow disturbing elements 211, which are arranged in rows and lines to together define a plurality of first liquid passages 251 between them. The second flow disturbing member 22 includes a plurality of second flow disturbing elements 221, which are arranged in rows and lines to together define a plurality of second liquid passages 252 between them. In the illustrated first embodiment, the first and second flow disturbing elements 211, 221 are respectively a wave-shaped plate. However, it is understood the first and second flow disturbing elements 211, 221 are not necessarily limited to wave-shaped plates. In practical implementation of the present invention, the first and second flow disturbing elements 211, 221 can be otherwise helical-shaped elements or any other geometric-shaped elements, such as square, rectangular or rhombic elements, arranged in rows and lines side-by-side. According to the present invention, any structure that can produce a flow disturbing or stirring effect to lower liquid flow speed and increase liquid flow time in the liquid chambers of the water-cooling radiator assembly 2 is included in the scope of the first and the second flow disturbing member 21, 22 of the present invention. Any two adjacent first flow disturbing elements 211 located in the same row and in two adjacent rows have shapes that are inverted relative to each other. The first flow disturbing elements 211 are located in the first liquid chamber 2014a to function as an internal structural support to the first liquid-receiving plate 201. The first flow disturbing elements 211 are respectively formed with a first flow disturbing means 2111, which is located on one side of each first flow disturbing element 211 that faces toward the first liquid passage 251.

Similarly, any two adjacent second flow disturbing elements 221 located in the same row and in two adjacent rows have shapes that are inverted relative to each other. The second flow disturbing elements 221 are located in the second liquid chamber 2014b to function as an internal structural support to the first liquid-receiving plate 201. The second flow disturbing elements 221 are respectively formed with a second flow disturbing means 2211, which is located on one side of each second flow disturbing element 221 that faces toward the second liquid passage 252. In an operable embodiment of the present invention, the first and the second flow disturbing means 2111, 2211 can be omitted from the first and the second flow disturbing elements 211, 221, respectively. In another operable embodiment, the first and the second flow disturbing member 21, 22 are integrally formed with the first partition member 2013 by way of, for example, 3D printing.

When the heat-carrying working liquid 4 flows into the second liquid chamber 2014b via the liquid inlet 2017 on the first liquid-receiving plate 201 and further flows through the second flow disturbing member 22 in the second liquid chamber 2014b, the working liquid 4 is disturbed and stirred by the second flow disturbing elements 221, so that streams of the working liquid 4 flowed through different second flow disturbing elements 221 reach a homogeneous temperature. Also, the working liquid 4 flowing through the second liquid passages 252 will strike against the second flow disturbing means 2211 to produce eddies, which increases the flow time of the working liquid 4 in the second liquid chamber 2014b and enables enhanced working liquid streams mixing effect and accordingly, effectively upgraded heat exchange efficiency. Meanwhile, heat carried by the working liquid 4 is directly absorbed by inner surfaces of the first liquid-receiving plate 201 and transferred to an outer side of the first liquid-receiving plate 201, from where the heat is dissipated into ambient air. After flowing through the second liquid passages 252, the working liquid 4 flows into the fourth liquid chamber 2024b via the first opening 2015a and the first communicating pipe 271. At this point, any heat remained in the working liquid 4 will be directly absorbed by inner surfaces of the second liquid-receiving plate 202 and transferred to an outer side of the second liquid-receiving plate 202, from where the heat is dissipated into ambient air. Then, the cooled working liquid 4 in the fourth liquid chamber 2024b flows into the first liquid chamber 2014a of the first liquid-receiving plate 201 via the sixth opening 2025c and the second communicating pipe 272. When the working liquid 4 flows through the first flow disturbing member 21 in the first liquid chamber 2014a, the working liquid 4 is disturbed and stirred by the first flow disturbing elements 211, so that streams of the working liquid 4 flowed through different first flow disturbing elements 211 reach a homogeneous temperature. Also, the working liquid 4 flowing through the first liquid passages 251 will strike against the first flow disturbing means 2111 to produce eddies, which increases the flow time of the working liquid 4 in the first liquid chamber 2014a and enables enhanced working liquid streams mixing effect and accordingly, effectively upgraded heat exchange efficiency. Meanwhile, the working liquid 4 flowing through the first flow passages 251 also absorbs the heat carried by the working liquid 4 that is currently in the second liquid chamber 2014b below the first partition member 2013, so that the working liquid 4 in the first liquid-receiving plate 201 can reach the homogenous temperature more efficiently through effective heat exchange and quick heat dissipation. Then, the working liquid 4, which is currently in the first liquid chamber 2014a and has just absorbed heat through heat exchange with the working liquid 4 in the second liquid chamber 2014b, flows through the first liquid passages 251 into the third liquid chamber 2024a via the third opening 2015b and the third communicating pipe 273. At this point, the heat carried by the working liquid 4 is directly absorbed by the inner surfaces of the second liquid-receiving plate 202 and transferred to the outer side of the second liquid-receiving plate 202, from where the heat is dissipated into ambient air. Finally, the cooled working liquid 4 leaves the second liquid-receiving plate 202 via the liquid outlet 2027.

Therefore, by providing the first and second partition members 2013, 2023 in the first and second liquid-receiving plates 201, 202, respectively, to form two independent horizontal liquid chambers in each of the first and the second liquid-receiving plate 201, 202, and by separately providing the first and the second flow disturbing member 21, 22 in the two independent liquid chambers in the first liquid-receiving plate 201, it is able to effectively extend the flow path and the flow time of the working liquid 4 in the first liquid-receiving plate 201 and accordingly, achieve the effects of more efficient heat exchange and quicker heat dissipation. More specifically, the first and the second flow disturbing elements 211, 221 of the first and the second flow disturbing member 21, 22, respectively, not only disturb and stir the working liquid 4 to extend the flow time of the working liquid 4 and enhance the mixing of different streams of the working liquid 4 in the liquid-receiving plate unit 20 to effectively upgrade the efficiency of heat exchange between the working liquid 4 and the first liquid-receiving plate 201, but also provide largely increased heat transfer areas to absorb and transfer the heat carried by the working liquid 4 to the corresponding first and second liquid-receiving plates 201, 202, from where the heat is dissipated into ambient air to achieve largely upgraded heat dissipation efficiency. The first and the second liquid-receiving plate 201, 202 of the liquid-receiving plate unit 20 also have relatively large inner surfaces, which are in direct contact with the flowing working liquid 4 to absorb the heat carried by the working liquid 4. The heat directly absorbed by the inner surfaces of the first and the second liquid-receiving plate 201, 202 is then quickly dissipated into ambient air from the relatively large outer surfaces of the first and the second liquid-receiving plate 201, 202. These arrangements enable the water-cooling radiator assembly 2 according to the first embodiment of the present invention to have increased heat dissipation areas and achieve good heat removal performance.

In an operable embodiment of the present invention, the first and the second liquid-receiving plate 201, 202 as well as the first communicating pipe 271 are made of a titanium material having a purity of 90% to 99.99%, such as the commercially pure titanium (CP-Ti). The titanium material has high metal strength, low weight and good heat transfer efficiency and is corrosion resistant to enable effectively upgraded heat transfer effect and reduced overall weight of the water-cooling radiator assembly 2. In the structural design of the present invention that combines the liquid-receiving plate unit 20 and the communicating pipe unit 27, the number and positions of the liquid-receiving plates as well as the number and positions of the communicating pipes between any two adjacent liquid-receiving plates can be actively adjusted or arranged in advance according to the internal space available in an electronic device (not shown) that requires water cooling, so that the heat dissipation effect can be adjusted in different manners.

The water-cooling radiator assembly 2 of the present invention can be applied to electronic equipment, industrial equipment, household appliances, transportation equipment, smart equipment and devices, etc. to cool or dissipate heat from the heat-producing electronic elements or heat sources in these equipment, appliances or devices.

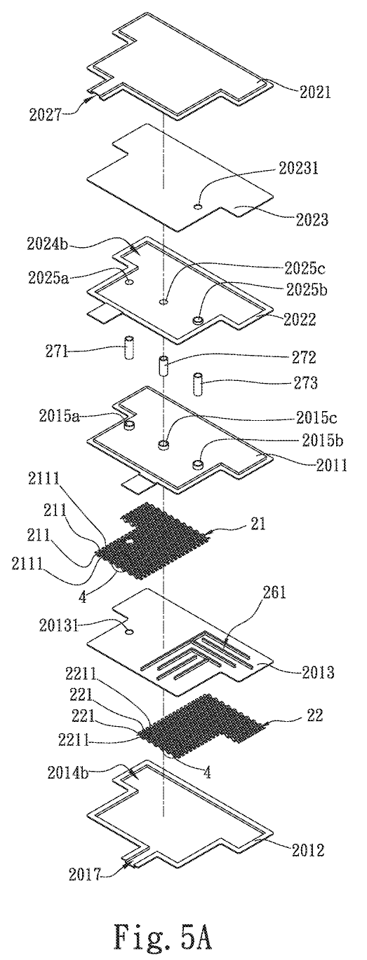

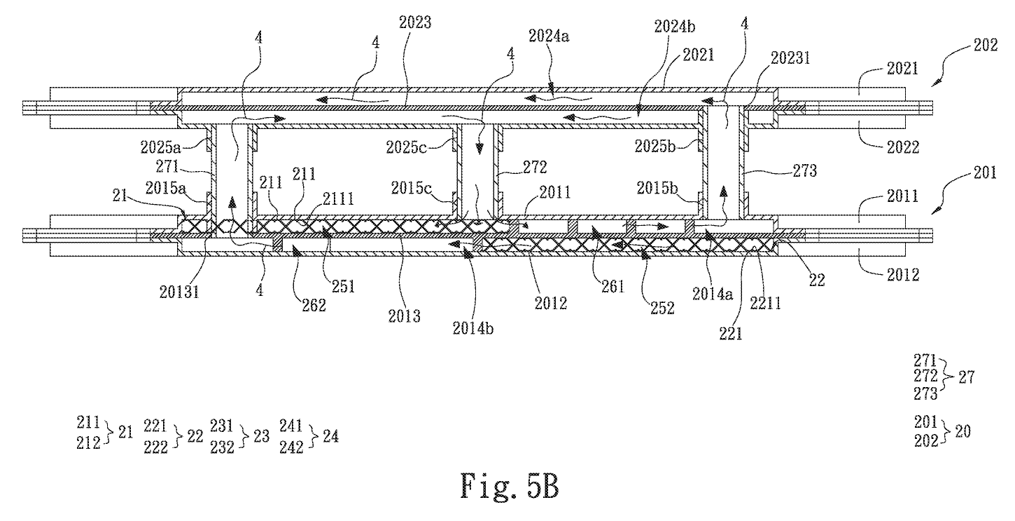

Please refer to FIGS. 5A and 5B that are exploded perspective and assembled sectional views, respectively, of a water-cooling radiator assembly 2 according to a second embodiment of the present invention, and to FIG. 4 again that is also an enlarged view of the circled area 4 in FIG. 5A. As shown, while the second embodiment has first and second liquid-receiving plates 201, 202, first and second flow disturbing members 21, 22, and first, second and third communicating pipes 271, 272, 273 that are generally structurally the same as those in the first embodiment, the second embodiment is different from the first one in further including a first flow passage 261 and a second flow passage 262. The first flow passage 261 is provided in the first liquid chamber 2014a at a position laterally opposite to the first flow disturbing member 21. In the second embodiment shown in FIGS. 5A and 5B, the first flow passage 261 is located at a right zone in the first liquid chamber 2014a while the first flow disturbing member 21 is located at a left zone in the first liquid chamber 2014a. Similarly, the second flow passage 262 is provided in the second liquid chamber 2014b at a position laterally opposite to the second flow disturbing member 22. In the second embodiment shown in FIGS. 5A and 5B, the second flow passage 262 is located at a left zone in the second liquid chamber 2014b while the second flow disturbing member 22 is located at a right zone in the second liquid chamber 2014b. The first and the second flow passage 261, 262 serve as guide paths for the working liquid 4 in the first and the second liquid-receiving plate 201, 202, respectively. In the illustrated second embodiment, the first flow passage 261 is formed on the upper surface of the first partition member 2013 and winding through the first liquid chamber 2014a, and the second flow passage 262 is formed on the lower surface of the first partition member 2013 and winding through the second liquid chamber 2014b. It is understood the arrangement of the first flow disturbing member 21 and the first flow passage 261 as well as the arrangement of the second flow disturbing member 22 and the second flow passage 262 in the first liquid-receiving plate 201 are not necessarily limited to the above-described positions. Any arrangement that disposes the first flow disturbing member 21 and the first flow passage 261 in the first liquid chamber 2014a and disposes the second flow disturbing member 22 and the second flow passage 262 in the second liquid chamber 2014b shall be included in the spirit and scope of the present invention.

In an operable embodiment of the present invention, the second flow passage 262 can be omitted from the second liquid chamber 2014b, so that the entire area, including the left and the right zone, in the second liquid chamber 2014b is occupied only by the second flow disturbing member 22.

According to the second embodiment, the working liquid 4 flowing through the second flow disturbing member 22 in the second liquid chamber 2014b is disturbed and stirred by the second flow disturbing elements 221, so that streams of the working liquid 4 flowed through different second flow disturbing elements 221 reach a homogeneous temperature. Then, the working liquid 4 flowing through the second liquid passages 252 will strike against the second flow disturbing means 2211 to produce eddies. After passing through the second liquid passages 252, the working liquid 4 flows along the winding second flow passage 262 toward the first opening 2015a, and then flows into the fourth liquid chamber 2024b via the first opening 2015a and the first communicating pipe 271. Then, the cooled working liquid 4 in the fourth liquid chamber 2024b flows into the first liquid chamber 2014a of the first liquid-receiving plate 201 via the sixth opening 2025c and the second communicating pipe 272. When the working liquid 4 flows through the first flow disturbing member 21 in the first liquid chamber 2014a, the working liquid 4 is disturbed and stirred by the first flow disturbing elements 211, so that streams of the working liquid 4 flowed through different first flow disturbing elements 211 reach a homogeneous temperature. Also, the working liquid 4 flowing through the first liquid passages 251 will strike against the first flow disturbing means 2111 to produce eddies. Meanwhile, the working liquid 4 flowing through the first flow passages 251 also absorbs the heat carried by the working liquid 4 that is currently in the second liquid chamber 2014b below the first partition member 2013, so that the working liquid 4 in the first liquid-receiving plate 201 can reach the homogenous temperature more efficiently through effective heat exchange and quick heat dissipation. Then, the working liquid 4, which is currently in the first liquid chamber 2014a and has just absorbed heat through heat exchange with the working liquid 4 in the second liquid chamber 2014b, flows through the first liquid passages 251 and keeps flowing along the winding first flow passage 261 toward the third opening 2015b. Thereafter, the working liquid 4 flows into the third liquid chamber 2024a via the third opening 2015b and the third communicating pipe 273. Finally, the cooled working liquid 4 leaves the second liquid-receiving plate 202 via the liquid outlet 2027. In brief, in the second embodiment of the present invention, the first liquid chamber 2014a is internally provided with two structures of different functions, i.e. the first flow disturbing member 21 and the first flow passage 261, while the second liquid chamber 2014b is also internally provided with another two structures of different functions, i.e. the second flow disturbing member 22 and the second flow passage 262. With these arrangements, it is able to lower the flow speed and increase the flow time of the working liquid 4 in the first liquid-receiving plate 201 and accordingly, largely upgrade the heat dissipation efficiency of the water-cooling radiator assembly 2 according to the second embodiment of the present invention.

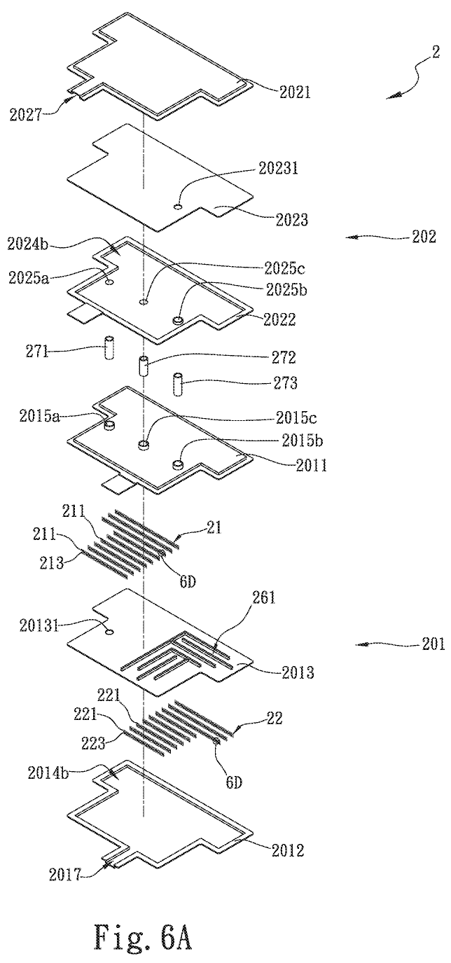

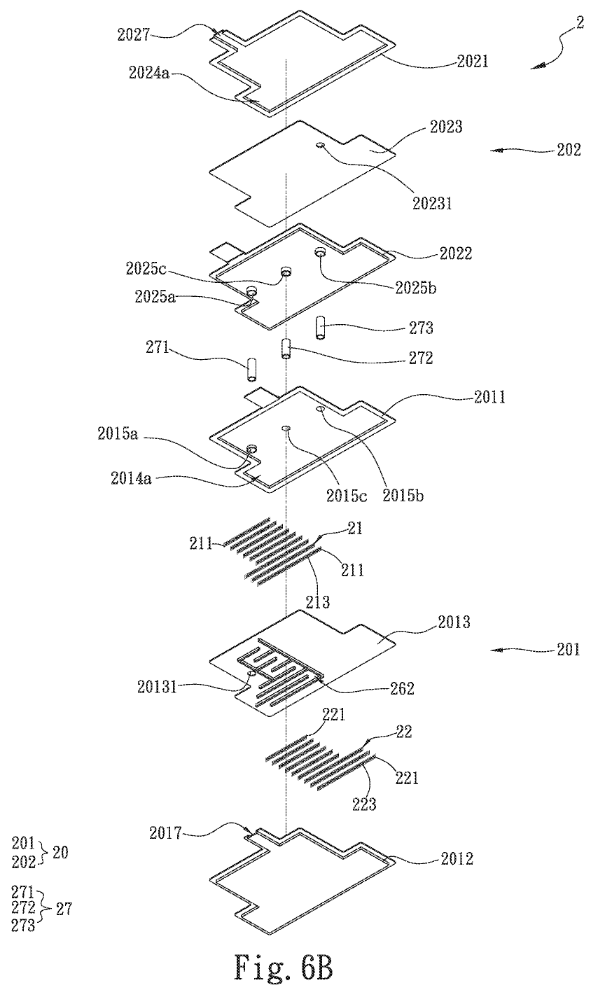

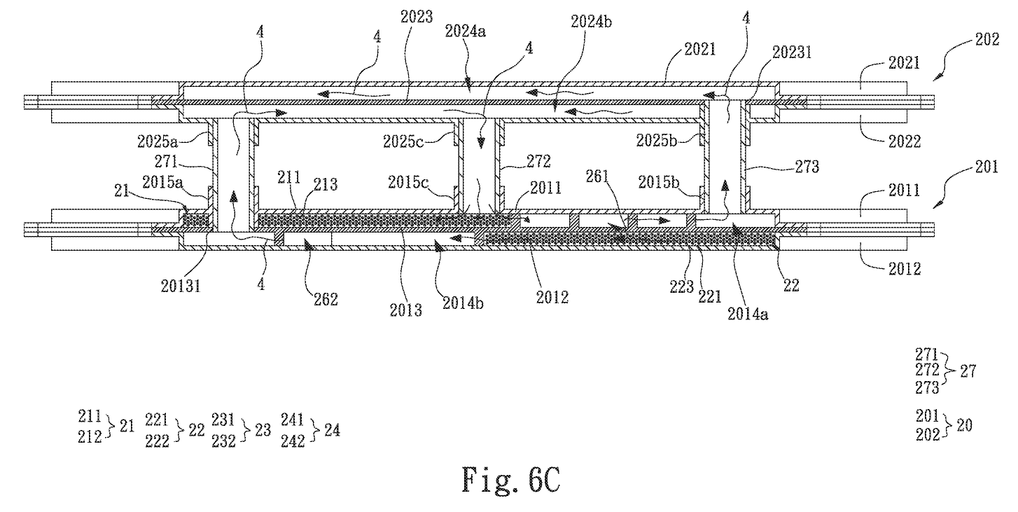

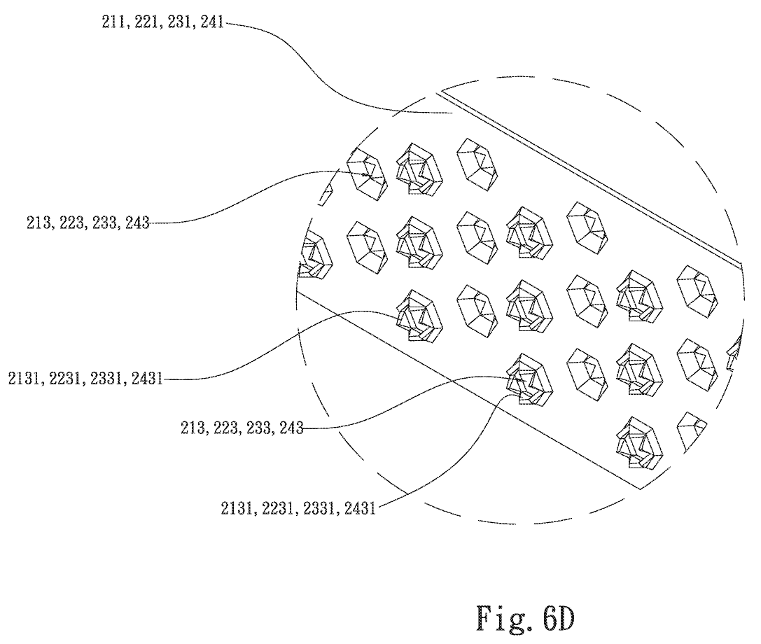

Please refer to FIGS. 6A and 6B, which are exploded top and bottom perspective views, respectively, of a water-cooling radiator assembly 2 according to a third embodiment of the present invention; and to FIG. 6C, which is an assembled sectional view of the third embodiment of the present invention; and to FIG. 6D, which is an enlarged view of the circled area 6D in FIG. 6A. As shown, in the third embodiment, the first and the second flow disturbing elements 211, 221 are respectively in the form of a geometric-shaped strip, such as a rectangular strip, instead of a wave-shaped plate as shown in the first and second embodiments. According to the third embodiment, the first flow disturbing elements 211 of the first flow disturbing member 21 are arranged in the first liquid chamber 2014a to be equally spaced from one another and located opposite to the first flow passage 261. Similarly, the second flow disturbing elements 221 of the second flow disturbing member 22 are arranged in the second liquid chamber 2014b to be equally spaced from one another and located opposite to the second flow passage 262. In an operable embodiment, the first flow disturbing elements 211 are unequally spaced from one another in the first liquid chamber 2014a while being located opposite to the first flow passage 261; and the second flow disturbing elements 221 are also unequally spaced from one another in the second liquid chamber 2014b while being located opposite to the second flow passage 262.

As can be clearly seen in FIG. 6D, each of the first flow disturbing elements 211 is provided with a plurality of first flow disturbing holes 213, which are so formed that they respectively penetrate the first flow disturbing element 211 with a first lip portion 2131 formed around each of them and protruded from two opposite side surfaces of the strip-shaped first flow disturbing element 211. It is noted some of the first flow disturbing holes 213 have their first lip portions 2131 protruded from one side surface of the strip-shaped first flow disturbing element 211, while others have their first lip portions 2131 protruded from the opposite side surface of the strip-shaped first flow disturbing element 211. Similarly, each of the second flow disturbing elements 221 is provided with a plurality of second flow disturbing holes 223, which are so formed that they respectively penetrate the second flow disturbing element 221 with a second lip portion 2231 formed around each of them and protruded from two opposite side surfaces of the strip-shaped second flow disturbing element 221. It is noted some of the second flow disturbing holes 223 have their second lip portions 2231 protruded from one side surface of the strip-shaped second flow disturbing element 221, while others have their second lip portions 2231 protruded from the opposite side surface of the strip-shaped second flow disturbing element 221.

In practical implementation of the third embodiment of the present invention, two opposite side surfaces of each of the first and the second flow disturbing elements 211, 221 are machined, for example, using a stamping mold to form the first and the second flow disturbing holes 213, 223, respectively. When the first and the second flow disturbing elements 211, 221 are stamped from a first side surface thereof to form the first and the second flow disturbing holes 213, 223, respectively, the first and the second lip portion 2131, 2231 will be formed on and protruded from an opposite second side surface of the first and the second flow disturbing elements 211, 221 around the so formed flow disturbing holes 213, 223. On the other hand, when the first and the second flow disturbing elements 211, 221 are stamped from the second side surface thereof to form the first and the second flow disturbing holes 213, 223, respectively, the first and the second lip portion 2131, 2231 will be formed on and protruded from the first side surface of the first and the second flow disturbing elements 211, 221 around the so formed flow disturbing holes 213, 223. When the working liquid 4 flows through the first and the second flow disturbing holes 213, 223, it strikes against the first and the second lip portions 2131, 2231, respectively, and is disturbed and stirred to extend its flow time in the first and the second liquid chamber 2014a, 2014b accordingly. Therefore, with the structural design of the first and the second flow disturbing elements 211, 221 that have the first and the second flow disturbing holes 213, 223 as well as the first and the second lip portions 2131, 2231 correspondingly formed thereon, the working liquid 4 passing through the first and the second flow disturbing holes 213, 223 will correspondingly strike against and be disturbed by the first and the second lip portions 2131, 2231 to increase the flow time of the working liquid 4 in the liquid-receiving plate unit 20 to thereby largely upgrade the heat dissipation efficiency or the heat exchange efficiency of the water-cooling radiator assembly 2 according to the third embodiment of the present invention. According to the third embodiment, the first and the second flow disturbing holes 213, 223 can be respectively a hexagonal hole, or any other polygonal hole, such as a triangular, a pentagonal or an octagonal hole, or any other geometric-shaped hole, such as a square or a rhombic hole.

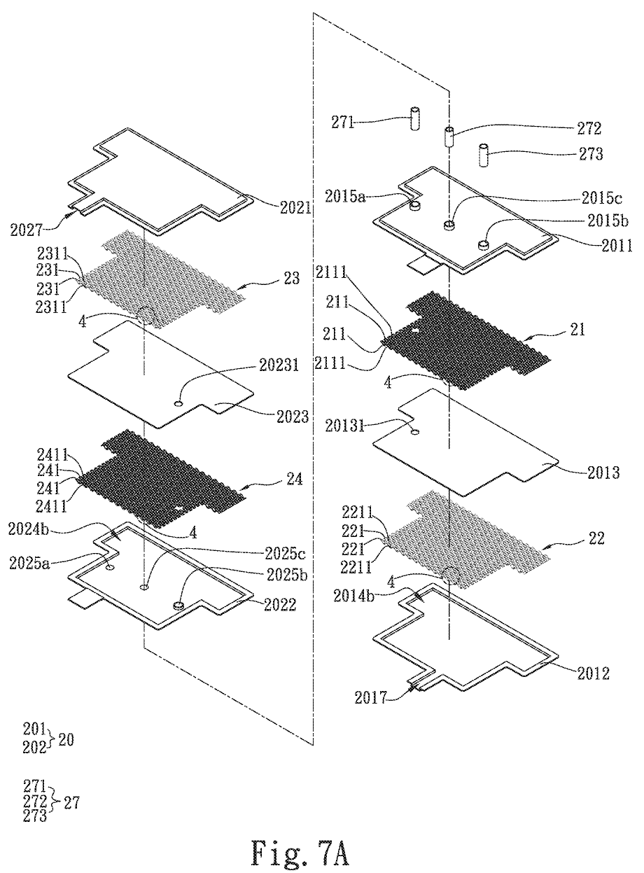

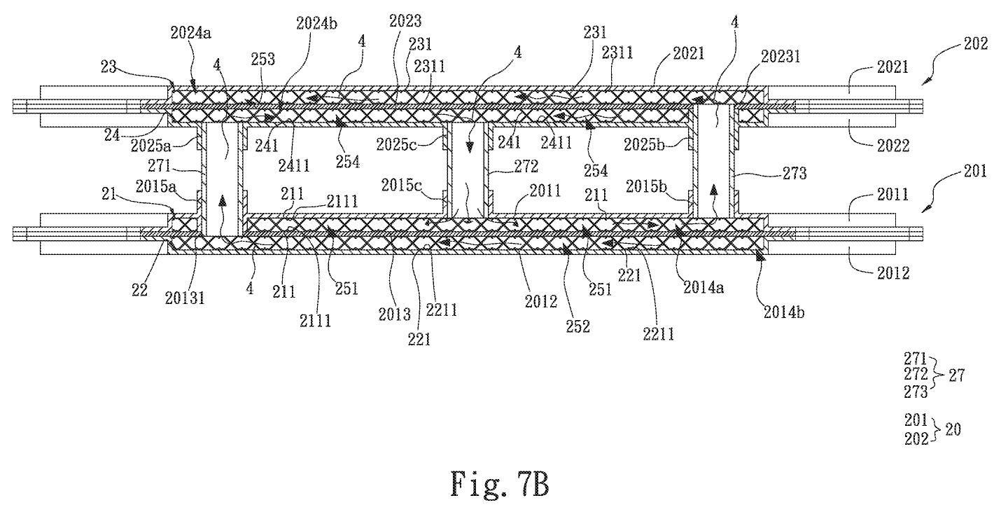

Please refer to FIGS. 7A and 7B, which are exploded top perspective and assembled sectional views, respectively, of a water-cooling radiator assembly 2 according to a fourth embodiment of the present invention; and to FIG. 4 again, which is also an enlarged view of the circled area 4 in FIG. 7A. As shown, the fourth embodiment is different from the first embodiment in further including a third flow disturbing member 23 and a fourth flow disturbing member 24, which provide the effects of disturbing liquid flows and forming a support in the second liquid-receiving plate 202. The third and the fourth flow disturbing member 23, 24 can be made of gold, silver, copper, iron, titanium, aluminum or stainless steel, or any alloy of these metal materials. The third and the fourth flow disturbing member 23, 24 are arranged in the third liquid chamber 2024a and the fourth liquid chamber 2024b, respectively. In the illustrated fourth embodiment, the third flow disturbing member 23 in the third liquid chamber 2024a has an upper side in contact with an inner surface of the second top plate member 2021 and a lower side in contact with an upper surface of the second partition member 2023; and the fourth flow disturbing member 24 in the fourth liquid chamber 2024b has an upper side in contact with a lower surface of the second partition member 2023 and a lower side in contact with an inner surface of the second bottom plate member 2022.

As shown, the third flow disturbing member 23 includes a plurality of third flow disturbing elements 231, which are arranged in rows and lines to together define a plurality of third liquid passages 253 between them. The fourth flow disturbing member 24 includes a plurality of fourth flow disturbing elements 241, which are arranged in rows and lines to together define a plurality of fourth liquid passages 254 between them.

In the illustrated fourth embodiment, the third and fourth flow disturbing elements 231, 241 are respectively a wave-shaped plate. However, it is understood the third and fourth flow disturbing elements 231, 241 are not necessarily limited to wave-shaped plates. In practical implementation of the present invention, the third and fourth flow disturbing elements 231, 241 can be otherwise helical-shaped elements or any other geometric-shaped elements, such as square, rectangular or rhombic elements, arranged in rows and lines side-by-side. According to the present invention, any structure that can produce a flow disturbing or stirring effect to lower liquid flow speed and increase liquid flow time in the liquid chambers of the water-cooling radiator assembly 2 is included in the scope of the third and the fourth flow disturbing member 23, 24 of the present invention. Any two adjacent third flow disturbing elements 231 located in the same row and in two adjacent rows have shapes that are inverted relative to each other. The third flow disturbing elements 231 are located in the third liquid chamber 2024a to function as an internal structural support to the second liquid-receiving plate 202. The third flow disturbing elements 231 are respectively formed with a third flow disturbing means 2311, which is located on one side of each third flow disturbing element 231 that faces toward the third liquid passage 253.

Similarly, any two adjacent fourth flow disturbing elements 241 located in the same row and in two adjacent rows have shapes that are inverted relative to each other. The fourth flow disturbing elements 241 are located in the fourth liquid chamber 2024b to function as an internal structural support to the second liquid-receiving plate 202. The fourth flow disturbing elements 241 are respectively formed with a fourth flow disturbing means 2411, which is located on one side of each fourth flow disturbing element 241 that faces toward the fourth liquid passage 254. In an operable embodiment of the present invention, the third and the fourth flow disturbing means 2311, 2411 can be omitted from the third and the fourth flow disturbing elements 231, 241, respectively. In another operable embodiment, the third and the fourth flow disturbing member 23, 24 are integrally formed with the second partition member 2023 by way of, for example, 3D printing. The provision of the third and the fourth flow disturbing member 23, 24 can extend the flow time of the working liquid 4 and enhance the mixing of different streams of the working liquid 4 in the liquid-receiving plate unit 20 to effectively upgrade the efficiency of heat exchange between the working liquid 4 and the first and second liquid-receiving plates 201, 202 and achieve largely upgraded heat dissipation efficiency of the whole water-cooling radiator assembly 2.

According to an operable embodiment, the second and the fourth flow disturbing member 22, 24 can be omitted from the water-cooling radiator assembly 2 of the present invention. That is, only the first and the third liquid chamber 2014a, 2024a have the first and the third flow disturbing member 21, 23, respectively, provided therein. Alternatively, according to another operable embodiment, the first and the third flow disturbing member 21, 23 are omitted from the water-cooling radiator assembly 2 of the present invention. That is, only the second and the fourth liquid chamber 2014b, 2024b have the second and the fourth flow disturbing member 22, 24, respectively, provided therein. Or, according to a further operable embodiment, the third flow disturbing member 23 is omitted from the water-cooling radiator assembly 2 of the present invention. That is, only the first, the second and the fourth liquid chamber 2014a, 2014b, 2024b have the first, the second and the fourth flow disturbing member 21, 22, 24, respectively, provided therein.

Therefore, the water-cooling radiator assembly 2 with internal horizontal partition members 2013, 2023 and fluid disturbing members 21, 22, 23, 24 can have good heat removal performance and provide the effects of efficient heat exchange and quick heat dissipation. Since the structure of the present invention can effectively increase the flow time of the working liquid 4 in the water-cooling radiator assembly 2, the working liquid 4 can have sufficient time to exchange heat with the first and the second liquid-receiving plate 201, 202, enabling the present invention to have largely upgraded heat dissipation efficiency.

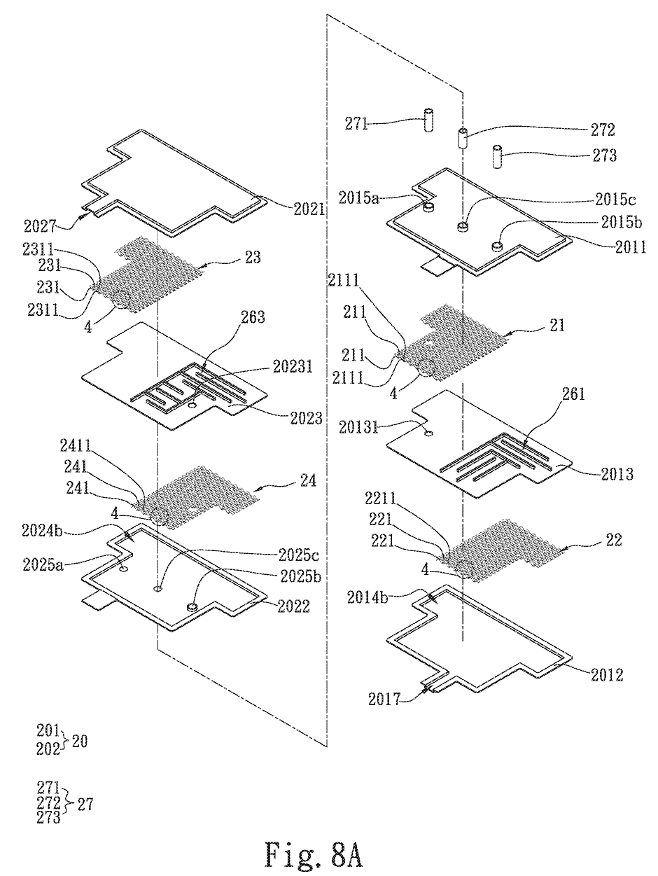

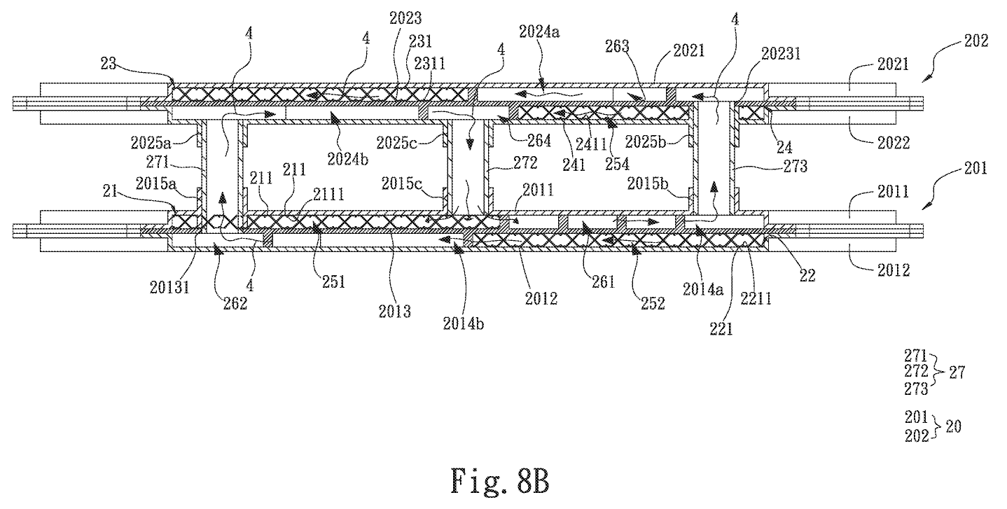

Please refer to FIGS. 8A and 8B, which are exploded top perspective and assembled sectional views, respectively, of a water-cooling radiator assembly 2 according to a fifth embodiment of the present invention; and to FIG. 4 again, which is also an enlarged view of the circled area 4 in FIG. 8A. As shown, the fifth embodiment includes first and second liquid-receiving plates 201, 202 and first, second and third communicating pipes 271, 272, 273 that are structurally and functionally similar to those in the fourth embodiment. However, according to the fifth embodiment, the first, second, third and fourth flow disturbing members 21, 22, 23, 24 are disposed in the first, second, third and fourth liquid chambers 2014a, 2014b, 2024a, 2024b, respectively, at a lateral zone thereof. For example, in the illustrated fifth embodiment, the first and the third flow disturbing member 21, 23 are disposed in the first and the third liquid chamber 2014a, 2024a, respectively, at a left zone thereof, while the second and the fourth flow disturbing member 22, 24 are disposed in the second and the fourth liquid chamber 2014b, 2024b, respectively, at a right zone thereof. Further, the fifth embodiment is different from the fourth one in further including a first, a second, a third and a fourth flow passage 261, 262, 263, 264, which are located in the first, second, third and fourth liquid chambers 2014a, 2014b, 2024a, 2024b, respectively, at another lateral zone thereof. For example, in the illustrated fifth embodiment, the first and the third flow passage 261, 263 are located in the first and the third liquid chamber 2014a, 2024a, respectively, at a right zone thereof, while the second and the fourth flow passage 262, 264 are located in the second and the fourth liquid chamber 2014b, 2024b, respectively, at a left zone thereof.

As shown, according to the fifth embodiment, the first flow disturbing member 21 and the first flow passage 261 in the first liquid chamber 2014a as well as the second flow disturbing member 22 and the second flow passage 262 in the second liquid chamber 2014b are structurally and functionally similar to those in the second embodiment, and are therefore not repeatedly described herein. Also, according to the fifth embodiment, since the flowing and the effects of the working liquid 4 in the first and second liquid-receiving plates 201, 202, the first and second flow disturbing members 21, 22, the first and second flow passages 261, 262, as well as the first, second and third communicating pipes 271, 272, 273 are similar to those in the second embodiment, they are not repeatedly described herein.

The fifth embodiment is different from the second embodiment in further including the third flow passage 263 and the fourth flow passage 264. The third flow passage 263 is provided in the third liquid chamber 2024a at a position laterally opposite to the third flow disturbing member 23. As can be seen in FIG. 8B, in the illustrated fifth embodiment, the third flow passage 263 is located at a right zone in the third liquid chamber 2024a while the third flow disturbing member 23 is located at a left zone in the third liquid chamber 2024a. On the other hand, the fourth flow passage 264 is provided in the fourth liquid chamber 2024b at a position laterally opposite to the fourth flow disturbing member 24. As can be seen in FIG. 8B, in the illustrated fifth embodiment, the fourth flow passage 264 is located at a left zone in the fourth liquid chamber 2024b while the fourth flow disturbing member 24 is located at a right zone in the fourth liquid chamber 2024b. The third and the fourth flow passage 263, 264 serve as guide paths for the working liquid 4 in the third and the fourth liquid-receiving plate 201, 202, respectively. In the illustrated fifth embodiment, the third flow passage 263 is formed on an upper surface of the second partition member 2023 and winding through the third liquid chamber 2024a, and the fourth flow passage 264 is formed on a lower surface of the second partition member 2023 and winding through the fourth liquid chamber 2024b. It is understood the arrangement of the third flow disturbing member 23 and the third flow passage 263 as well as the arrangement of the fourth flow disturbing member 24 and the fourth flow passage 264 in the second liquid-receiving plate 202 are not necessarily limited to the above-described positions. Any arrangement that disposes the third flow disturbing member 23 and the third flow passage 263 in the third liquid chamber 2024a and disposes the fourth flow disturbing member 24 and the fourth flow passage 264 in the fourth liquid chamber 2024b shall be included in the spirit and scope of the present invention. In an operable embodiment, the fourth flow passage 264 can be omitted from the fourth liquid chamber 2024b, so that the entire area, including the left and the right zone, in the fourth liquid chamber 2024b is occupied only by the fourth flow disturbing member 24.

According to the fifth embodiment, when the working liquid 4 flows into the fourth liquid chamber 2024b via the first communicating pipe 271 and passes the fourth flow disturbing elements 241, the working liquid 4 is disturbed and stirred by the fourth flow disturbing elements 241, so that streams of the working liquid 4 flowed through different fourth flow disturbing elements 241 reach a homogeneous temperature. Then, the working liquid 4 flowing through the fourth liquid passages 254 will strike against the fourth flow disturbing means 2411 to produce eddies. After passing through the fourth liquid passages 254, the working liquid 4 flows along the winding fourth flow passage 264 toward the sixth opening 2015c. Then the partially cooled working liquid 4 flows into the first liquid chamber 2014a of the first liquid-receiving plate 201 via the sixth opening 2015c and the second communicating pipe 272. When the working liquid 4 flows through the first flow disturbing member 21 in the first liquid chamber 2014a, the working liquid 4 is disturbed and stirred by the first flow disturbing elements 211, so that streams of the working liquid 4 flowed through different first flow disturbing elements 211 reach a homogeneous temperature. Also, the working liquid 4 flowing through the first liquid passages 251 will strike against the first flow disturbing means 2111 to produce eddies. Meanwhile, the working liquid 4 flowing through the first liquid passages 251 also absorbs the heat carried by the working liquid 4 that is currently in the second liquid chamber 2014b below the first partition member 2013, so that the working liquid 4 in the first liquid-receiving plate 201 can reach the homogenous temperature more efficiently through effective heat exchange and quick heat dissipation. Then, the working liquid 4, which is currently in the first liquid chamber 2014a and has just absorbed heat through heat exchange with the working liquid 4 in the second liquid chamber 2014b, flows through the first liquid passages 251 and keeps flowing along the winding first flow passage 261 toward the third opening 2015b. Thereafter, the working liquid 4 flows into the third liquid chamber 2024a via the third opening 2015b and the third communicating pipe 273 to flow along the winding third flow passage 263 toward the liquid outlet 2027. When passing the third flow disturbing member 23, the working liquid 4 is disturbed and stirred by the third flow disturbing elements 231, so that streams of the working liquid 4 flowed through different third flow disturbing elements 231 reach a homogeneous temperature. Then, the working liquid 4 flowing through the third liquid passages 253 will strike against the third flow disturbing means 2311 to produce eddies. Finally, after passing the third liquid passages 253, the cooled working liquid 4 leaves the second liquid-receiving plate 202 via the liquid outlet 2027. With these arrangements, the water-cooling radiator assembly 2 according to the fifth embodiment of the present invention can have effectively improved heat removal performance and sufficient heat exchange to achieve quick heat dissipation effect; and the flow time of the working liquid 4 in the first and the second liquid-receiving plate 201, 202 is effectively increased to enable largely upgraded heat dissipation efficiency of the water-cooling radiator assembly 2 of the present invention.

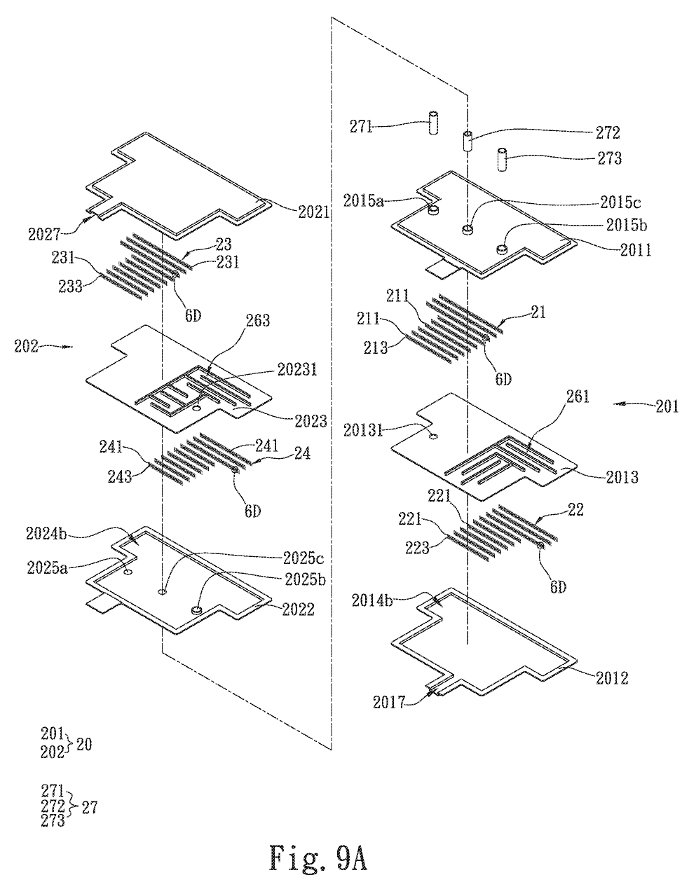

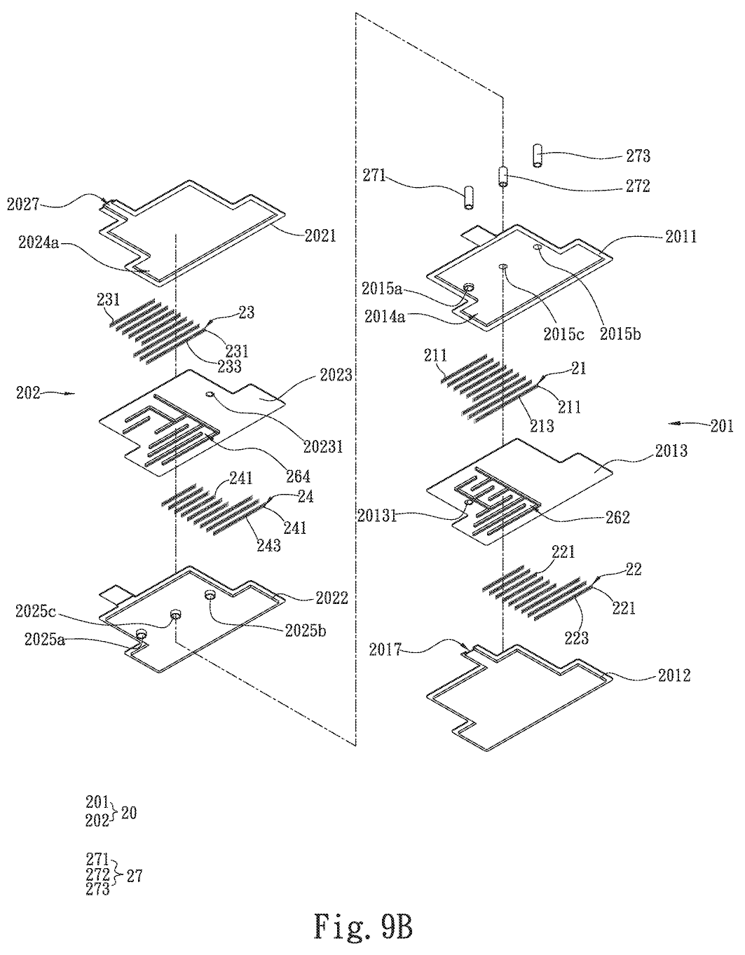

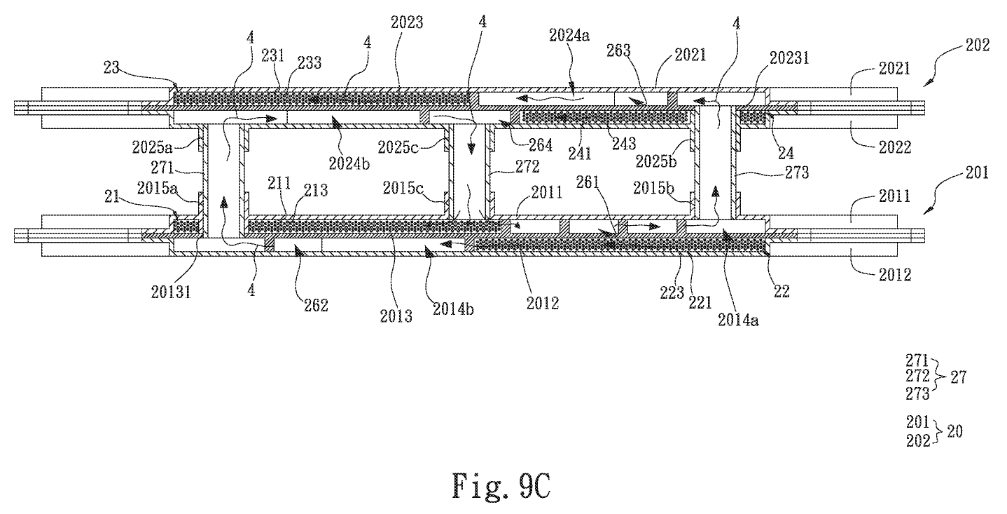

Please refer to FIGS. 9A and 9B, which are exploded top and bottom perspective views, respectively, of a water-cooling radiator assembly 2 according to a sixth embodiment of the present invention; and to FIG. 9C, which is an assembled sectional view of the sixth embodiment of the present invention; and to FIG. 6D, which is also an enlarged view of the circled area 6D in FIG. 9A. As shown, in the sixth embodiment, the first, the second, the third and the fourth flow disturbing elements 211, 221, 231, 241 are respectively in the form of a geometric-shaped strip, such as a rectangular strip, instead of a wave-shaped plate as shown in the fifth embodiment. Also, since the first and the second flow disturbing elements 211, 221 as well as the first and the second flow passage 261, 262 in the sixth embodiment are structurally and functionally similar to those in the third embodiment, they are not repeatedly described herein. According to the sixth embodiment, the third flow disturbing elements 231 of the third flow disturbing member 23 are arranged in the third liquid chamber 2024a to be equally spaced from one another and located opposite to the third flow passage 263. Similarly, the fourth flow disturbing elements 241 of the fourth flow disturbing member 24 are arranged in the fourth liquid chamber 2024b to be equally spaced from one another and located opposite to the fourth flow passage 264. In an operable embodiment, the third flow disturbing elements 231 are unequally spaced from one another in the third liquid chamber 2024a while being located opposite to the third flow passage 263; and the fourth flow disturbing elements 224 are also unequally spaced from one another in the fourth liquid chamber 2024b while being located opposite to the fourth flow passage 264.

As can be clearly seen in FIG. 6D, each of the third flow disturbing elements 231 is provided with a plurality of third flow disturbing holes 233, which are so formed that they respectively penetrate the third flow disturbing element 231 with a third lip portion 2331 formed around each of them and protruded from two opposite side surfaces of the strip-shaped third flow disturbing element 231. It is noted some of the third flow disturbing holes 233 have their third lip portions 2331 protruded from one side surface of the strip-shaped third flow disturbing element 231, while others have their third lip portions 2331 protruded from the opposite side surface of the strip-shaped third flow disturbing element 231. Similarly, each of the fourth flow disturbing elements 241 is provided with a plurality of fourth flow disturbing holes 243, which are so formed that they respectively penetrate the fourth flow disturbing element 241 with a fourth lip portion 2431 formed around each of them and protruded from two opposite side surfaces of the strip-shaped fourth flow disturbing element 241. It is noted some of the fourth flow disturbing holes 243 have their fourth lip portions 2431 protruded from one side surface of the strip-shaped fourth flow disturbing element 241, while others have their fourth lip portions 2431 protruded from the opposite side surface of the strip-shaped fourth flow disturbing element 241. According to the sixth embodiment, the first, second, third and fourth flow disturbing holes 213, 223, 233, 243 can be respectively a hexagonal hole, or any other polygonal hole, or any other geometric-shaped hole.

In practical implementation of the sixth embodiment of the present invention, just like the first and the second flow disturbing elements 211, 221, each of the third and the fourth flow disturbing elements 231, 241 are machined, for example, using a stamping mold to form the third and the fourth flow disturbing holes 233, 243, respectively. Since the forming of the first and the second flow disturbing holes 213, 223 on the first and the second flow disturbing elements 211, 221 has been described in the third embodiment of the present invention, the forming of the third and the fourth flow disturbing holes 233, 243 is not repeatedly described herein. Therefore, with the structural design of the first, the second, the third and the fourth flow disturbing elements 211, 221, 231, 241 that have the first, the second, the third and the fourth flow disturbing holes 213, 223, 233, 243 as well as the first, the second, the third and the fourth lip portions 2131, 2231, 2331, 2431 correspondingly formed thereon, the working liquid 4 passing through the first, second, third and fourth flow disturbing holes 213, 223, 233, 243 will correspondingly strike against and be disturbed by the first, second, third and fourth lip portions 2131, 2231, 2331, 2431 to increase the flow time of the working liquid 4 in the liquid-receiving plate unit 20 to thereby largely upgrade the heat dissipation efficiency or the heat exchange efficiency of the water-cooling radiator assembly 2 according to the sixth embodiment of the present invention.

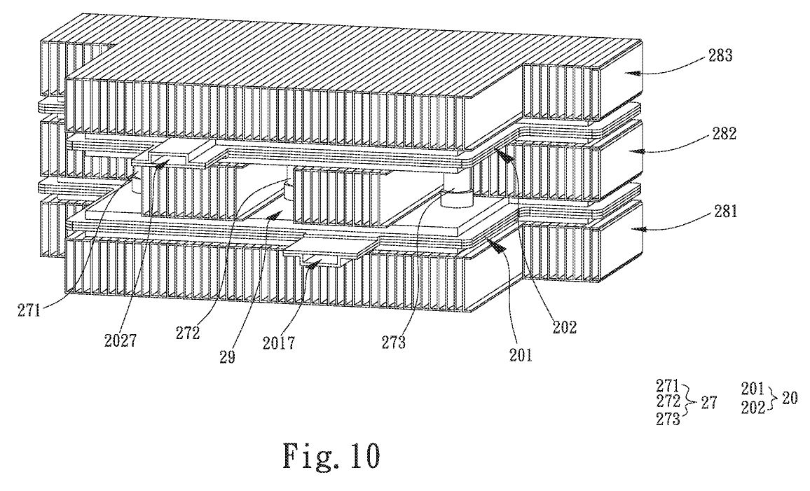

FIG. 10 is an assembled perspective view of a water-cooling radiator assembly 2 according to a seventh embodiment of the present invention. As shown, the seventh embodiment is different from the first embodiment in further including a first radiating fin assembly 281 consisting of a plurality of radiating fins and connected to an outer bottom side of the first liquid-receiving plate 201; a second radiating fin assembly 282 consisting of a plurality of radiating fins and arranged in a heat dissipation space 29 formed between the first and the second liquid-receiving plate 201, 202; and a third radiating fin assembly 283 consisting of a plurality of radiating fins and connected to an outer top side of the second liquid-receiving plate 202. Heat carried by the working liquid 4 and transferred to the outer surfaces of the first and the second liquid-receiving plate 201, 202 is further absorbed by the first, second and third radiating fin assemblies 281, 282, 283, from where the heat is quickly dissipated into ambient air to achieve good heat removal effect.

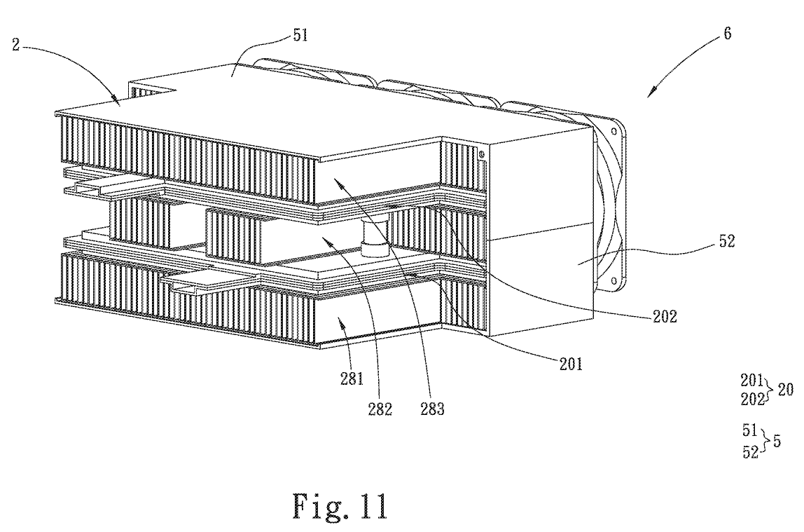

FIG. 11 is an assembled perspective view of a water-cooling radiator assembly 2 according to an eighth embodiment of the present invention. As shown, the eighth embodiment is different from the seventh embodiment in further including a protective cover unit 5 and a cooling fan bank 6. The protection cover unit 5 includes an upper protection cover 51 and a lower protection cover 52 covered onto an outer surface of the first and of the third radiating fin assembly 281, 283, respectively, to protect the first, the second and the third radiating fin assembly 281, 282, 283 against damages. The cooling fan bank 6 consists of a plurality of cooling fans connected to a lateral open side of the protection cover unit 5 to enable forced heat dissipation from the first, second and third radiating fin assemblies 281, 282, 283, so that heat is quickly removed from the first, second and third radiating fin assemblies 281, 282, 283.

In an operable embodiment, the protection cover unit 5 and the cooling fan bank 6 can be optionally omitted. In another operable embodiment, the protection cover unit 5 can be provided with a fastening unit (not shown) to firmly secure the water-cooling radiator assembly 2 to a carrier, such as a chassis or a motherboard.

In practical implementation of the present invention, the liquid outlet 2027 on the second liquid-receiving plate 202 is communicably connected to an end of a corresponding pump (not shown), and a cooling module (not shown) in contact with a heat source, such as a CPU or other heat-producing electronic element, can be correspondingly connected to another end of the pump and communicable with the liquid inlet 2017 on the first liquid-receiving plate 201, so that the water-cooling radiator assembly 2, the pump and the cooling module together constitute a water-cooling system. The pump drives or stirs the working liquid 4 to repeatedly circulate between the cooling module and the liquid-receiving plate unit 20 to effectively enable good heat removal performance and quick heat dissipation through heat exchange.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A water-cooling radiator assembly with internal horizontal partition members and fluid disturbing members, comprising:
a liquid-receiving plate unit including:
a first liquid-receiving plate having at least one liquid inlet provided thereon and a first partition member provided therein to divide an inner space of the first liquid-receiving plate into a first liquid chamber and a second liquid chamber; and the second liquid chamber being communicable with the at least one liquid inlet to allow a working liquid to flow into the second liquid chamber via the at least one liquid inlet; and
a second liquid-receiving plate having at least one liquid outlet provided thereon and a second partition member provided therein to divide an inner space of the second liquid-receiving plate into a third liquid chamber and a fourth liquid chamber; and the third liquid chamber being communicable with the at least one liquid outlet;
a first flow disturbing member being selectively arranged in any one of the first, the second, the third and the fourth liquid chamber; and
a communicating pipe unit including a first, a second and a third communicating pipe; the first communicating pipe communicating the second liquid chamber with the fourth liquid chamber, the second communicating pipe communicating the fourth liquid chamber with the first liquid chamber, and the third communicating pipe communicating the first liquid chamber with the third liquid chamber.

2. The water-cooling radiator assembly as claimed in claim 1, wherein the first liquid-receiving plate includes a first top plate member and a first bottom plate member; and the first partition member being located between the first top plate member and the first bottom plate member, such that the second liquid chamber is formed between the first bottom plate member and the first partition member while the first liquid chamber is formed between the first top plate member and the first partition member.

3. The water-cooling radiator assembly as claimed in claim 2, wherein the first flow disturbing member is arranged in the first liquid chamber, and has an upper side in contact with an inner surface of the first top plate member and a lower side in contact with an upper surface of the first partition member.

4. The water-cooling radiator assembly as claimed in claim 3, wherein the second liquid-receiving plate includes a second top plate member and a second bottom plate member; and the second partition member being located between the second top plate member and the second bottom plate member, such that the fourth liquid chamber is formed between the second bottom plate member and the second partition member while the third liquid chamber is formed between the second top plate member and the second partition member.

5. The water-cooling radiator assembly as claimed in claim 4, further comprising a second flow disturbing member; the second flow disturbing member being arranged in the second liquid chamber, and having an upper side in contact with a lower surface of the first partition member and a lower side in contact with an inner surface of the first bottom plate member.

6. The water-cooling radiator assembly as claimed in claim 5, further comprising a third flow disturbing member and a fourth flow disturbing member; the third flow disturbing member being arranged in the third liquid chamber, and having an upper side in contact with an inner surface of the second top plate member and a lower side in contact with an upper surface of the second partition member; the fourth flow disturbing member being arranged in the fourth liquid chamber, and having an upper side in contact with a lower surface of the second partition member and a lower side in contact with an inner surface of the second bottom plate member.

7. The water-cooling radiator assembly as claimed in claim 6, wherein the first flow disturbing member includes a plurality of first flow disturbing elements, which are arranged in rows and lines to together define a plurality of first liquid passages between them, and the first flow disturbing elements being respectively formed with a first flow disturbing means, which is located on one side of each first flow disturbing element that faces toward the first liquid passage; and wherein the second flow disturbing member includes a plurality of second flow disturbing elements, which are arranged in rows and lines to together define a plurality of second liquid passages between them, and the second flow disturbing elements being respectively formed with a second flow disturbing means, which is located on one side of each second flow disturbing element that faces toward the second liquid passage.

8. The water-cooling radiator assembly as claimed in claim 7, wherein the third flow disturbing member includes a plurality of third flow disturbing elements, which are arranged in rows and lines to together define a plurality of third liquid passages between them, and the third flow disturbing elements being respectively formed with a third flow disturbing means, which is located on one side of each third flow disturbing element that faces toward the third liquid passage; and
wherein the fourth flow disturbing member includes a plurality of fourth flow disturbing elements, which are arranged in rows and lines to together define a plurality of fourth liquid passages between them, and the fourth flow disturbing elements being respectively formed with a fourth flow disturbing means, which is located on one side of each fourth flow disturbing element that faces toward the fourth liquid passage.

9. The water-cooling radiator assembly as claimed in claim 8, wherein the first and second flow disturbing elements are respectively a wave-shaped plate; any two adjacent first flow disturbing elements located in the same row and in two adjacent rows having shapes that are inverted relative to each other, and any two adjacent second flow disturbing elements located in the same row and in two adjacent rows having shapes that are inverted relative to each other; and wherein the third and fourth flow disturbing elements are respectively a wave-shaped plate; any two adjacent third flow disturbing elements located in the same row and in two adjacent rows having shapes that are inverted relative to each other, and any two adjacent fourth flow disturbing elements located in the same row and in two adjacent rows having shapes that are inverted relative to each other.

10. The water-cooling radiator assembly as claimed in claim 6, wherein the first flow disturbing member includes a plurality of first flow disturbing elements; the first flow disturbing elements being arranged in the first liquid chamber to be selectively equally or unequally spaced from one another, and being respectively provided with a plurality of first flow disturbing holes, which respectively penetrate the first flow disturbing element; and wherein the second flow disturbing member includes a plurality of second flow disturbing elements; the second flow disturbing elements being arranged in the second liquid chamber to be selectively equally or unequally spaced from one another, and being respectively provided with a plurality of second flow disturbing holes, which respectively penetrate the second flow disturbing element.

11. The water-cooling radiator assembly as claimed in claim 10, wherein the third flow disturbing member includes a plurality of third flow disturbing elements; the third flow disturbing elements being arranged in the third liquid chamber to be selectively equally or unequally spaced from one another, and being respectively provided with a plurality of third flow disturbing holes, which respectively penetrate the third flow disturbing element; and wherein the fourth flow disturbing member includes a plurality of fourth flow disturbing elements; the fourth flow disturbing elements being arranged in the fourth liquid chamber to be selectively equally or unequally spaced from one another, and being respectively provided with a plurality of fourth flow disturbing holes, which respectively penetrate the fourth flow disturbing element; and the first, the second, the third and the fourth flow disturbing holes being hexagonal holes or any other polygonal holes or any other geometric-shaped holes.

12. The water-cooling radiator assembly as claimed in claim 6, further comprising a first flow passage and a second flow passage; the first flow passage being provided in the first liquid chamber at a position opposite to the first flow disturbing member, and the second flow passage being provided in the second liquid chamber at a position opposite to the second flow disturbing member.

13. The water-cooling radiator assembly as claimed in claim 12, further comprising a third flow passage and a fourth flow passage; the third flow passage being provided in the third liquid chamber at a position opposite to the third flow disturbing member, and the fourth flow passage being provided in the fourth liquid chamber at a position opposite to the fourth flow disturbing member.

14. The water-cooling radiator assembly as claimed in claim 4, wherein the first liquid-receiving plate further includes a first opening that penetrates the first top plate member, and the first partition member is provided with a first hole that penetrates the first partition member and is located corresponding to the first opening to communicate the first opening with the second liquid chamber; and the first communicating pipe having an end inserted into the first opening and the first hole to communicate with the second liquid chamber.

15. The water-cooling radiator assembly as claimed in claim 14, wherein the second liquid-receiving plate further includes a second opening that penetrates the second bottom plate member, and the first communicating pipe having another end communicably connected to the second opening, such that the first communicating pipe communicates the second liquid chamber with the fourth liquid chamber via the first opening and the second opening; and wherein the first liquid-receiving plate further includes a third opening and a fourth opening that penetrate the first top plate member; and the second communicating pipe having an end communicably connected to the fourth opening and the third communicating pipe having an end communicably connected to the third opening, such that the second and the third communicating pipe are communicable with the first liquid chamber.

16. The water-cooling radiator assembly as claimed in claim 15, wherein the second liquid-receiving plate further includes a fifth and a sixth opening that penetrate the second bottom plate member; the second communicating pipe having another end communicably connected to the sixth opening to thereby communicate the first liquid chamber with the fourth liquid chamber; the second partition member being provided with a second hole that penetrates the second partition member and is located corresponding to the fifth opening to communicate the fifth opening with the third liquid chamber; the third communicating pipe having another end inserted into the fifth opening and the second hole to communicate with the third liquid chamber, such that the third communicating pipe communicates the first liquid chamber with the third liquid chamber.

17. The water-cooling radiator assembly as claimed in claim 1, wherein the first and the second liquid-receiving plate as well as the first, second and third communicating pipes are made of a material selected from the group consisting of gold, silver, copper, iron, titanium, aluminum, stainless steel, and any alloy thereof.

18. The water-cooling radiator assembly as claimed in claim 1, wherein the second liquid chamber and the first liquid chamber are separated by the first partition member to form two independent chambers in the first liquid-receiving plate without being directly communicable with each other; wherein the fourth liquid chamber and the third liquid chamber are separated by the second partition member to form two independent chambers in the second liquid-receiving plate without being directly communicable with each other.

19. The water-cooling radiator assembly as claimed in claim 10, wherein the first flow disturbing holes formed on each of the first flow disturbing elements respectively have a first lip portion formed around them; and some of the first lip portions being protruded from one of two opposite side surfaces of the first flow disturbing element while other first lip portions being protruded from the other side surface of the first flow disturbing element; and wherein the second flow disturbing holes formed on each of the second flow disturbing elements respectively have a second lip portion formed around them; and some of the second lip portions being protruded from one of two opposite side surfaces of the second flow disturbing element while other second lip portions being protruded from the other side surface of the second flow disturbing element.

20. The water-cooling radiator assembly as claimed in claim 11, wherein the third flow disturbing holes formed on each of the third flow disturbing elements respectively have a third lip portion formed around them; and some of the third lip portions being protruded from one of two opposite side surfaces of the third flow disturbing element while other third lip portions being protruded from the other side surface of the third flow disturbing element; and wherein the fourth flow disturbing holes formed on each of the fourth flow disturbing elements respectively have a fourth lip portion formed around them; and some of the fourth lip portions being protruded from one of two opposite side surfaces of the fourth flow disturbing element while other fourth lip portions being protruded from the other side surface of the fourth flow disturbing element.
